(19) United States
(12) Patent Application Publication
(10) Pub. No.: US 2021/0218348 A1
(43) Pub. Date: Jul. 15, 2021

(54) THREE-PHASE FULL SiC INVERTER WITH ZERO-VOLTAGE SWITCHING CAPABILITY

(71) Applicants: Yanchao Li, CULVER CITY, CA (US); Ruigang Li, LOS ANGELES, CA (US); Zheng Zuo, LOS ANGELES, CA (US)

(72) Inventors: Yanchao Li, CULVER CITY, CA (US); Ruigang Li, LOS ANGELES, CA (US); Zheng Zuo, LOS ANGELES, CA (US)

(73) Assignee: AZ Power, Inc, CULVER CITY, CA (US)

(21) Appl. No.: 17/151,078

(22) Filed: Jan. 15, 2021

Related U.S. Application Data
(60) Provisional application No. 62/961,674, filed on Jan. 15, 2020.

(51) Int. Cl. H02M 7/5387; H03K 17/13

(52) U.S. Cl. CPC H02M 7/53875; H02M 2001/0003; H03K 17/133

(57) ABSTRACT

In one aspect, a power converter may include a plurality of inductor banks; a plurality of switches, each switch has a first power node and a second power node, and one control node that receives a control signal that maintains the switch in either ON state in which the circuit path between the first node and the second node are established, or OFF state in which the circuit path between the first node and the second node are eliminated; and a control logic that generates multiple signals that are applied to the control nodes of the switches. In one embodiment, the switches are MOSFETs; the first power nodes are drains and the second power nodes are sources, and the control nodes are gates.

### CROSS-REFERENCE TO RELATED APPLICATIONS

This application claims priority under 35 U.S.C. § 119 (e) to U.S. Provisional Patent Application Ser. No. 62/961,674, filed on Jan. 15, 2020, the entire contents of which are hereby incorporated by reference.

### FIELD OF THE INVENTION

The present invention relates to DC-AC power converters, and more particularly to DC-AC power converters that have soft-switching capability, which are also known as soft-switching power inverters.

### BACKGROUND OF THE INVENTION

Power inverter is a power electronic device that converts direct current (DC) to alternative current (AC). A power inverter usually includes power switches, control logics and filters. The applications of power inverters are very wide, such as induction heating application and electric motor drive application. By using pulse width modulation (PWM) technologies, a power inverter generates AC voltage with different frequencies at the output of the inverter with a DC voltage source at the input of the converter. One of the most common topology of power inverter is a three-phase half-bridge inverter. When silicon based insulated-gate bipolar transistor (IGBT) modules are used to build the power inverters, soft-switching techniques are usually implemented. On the other hand, when using SiC material-based devices as the main power switches in the circuit, hard switching is used.

### SUMMARY OF THE INVENTION

In one aspect, a power converter in the present invention may include a plurality of inductor banks, and each inductor bank has respective first and second node that are connected to respective circuit nodes in a circuit; a plurality of switches, and each switch has two power nodes and one control nodes that receives a control signal that maintains the switch in either ON state in which the circuit path between the first node and the second node are established, or OFF state in which the circuit path between the first node and the second node are eliminated, and the first and second node that are connected to respective circuit nodes in a circuit; and a control logic that generates first and second groups of signals that are applied to the control nodes of the first and second groups of switches, respectively.

Particular embodiments of the subject matter described in the present application can be implemented so as to realize one or more of the following advantages. The subject matter overcomes the weakness of high electromagnetic interference (EMI) issues in the conventional SiC devices based three-phase half-bridge inverter whose power switches are operating at hard-switching because the voltage magnitude across the first and second nodes of the switches will change rapidly during the switching transient between ON and OFF states. In addition, the power converter in the present invention has less power loss because of the implementation of zero-voltage switching technique for better efficiency.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1. illustrates the system level circuit structure of the three-phase DC to AC converter.

FIG. 2 illustrates the circuit diagram of the one phase circuit of the three-phase circuit shown in FIG. 1.

FIG. 3 illustrates the circuit diagram of the first sub-circuit of the one phase circuit shown in FIG. 2.

FIG. 4 illustrates the circuit diagram of the second sub-circuit of the one phase circuit shown in FIG. 2.

FIG. 5 illustrates the circuit diagram of the third sub-circuit of the one phase circuit shown in FIG. 2.

FIG. 6 illustrates the circuit diagram of the fourth sub-circuit of the one phase circuit shown in FIG. 2.

FIG. 7 illustrates the circuit diagram of the fifth sub-circuit of the one phase circuit shown in FIG. 2.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

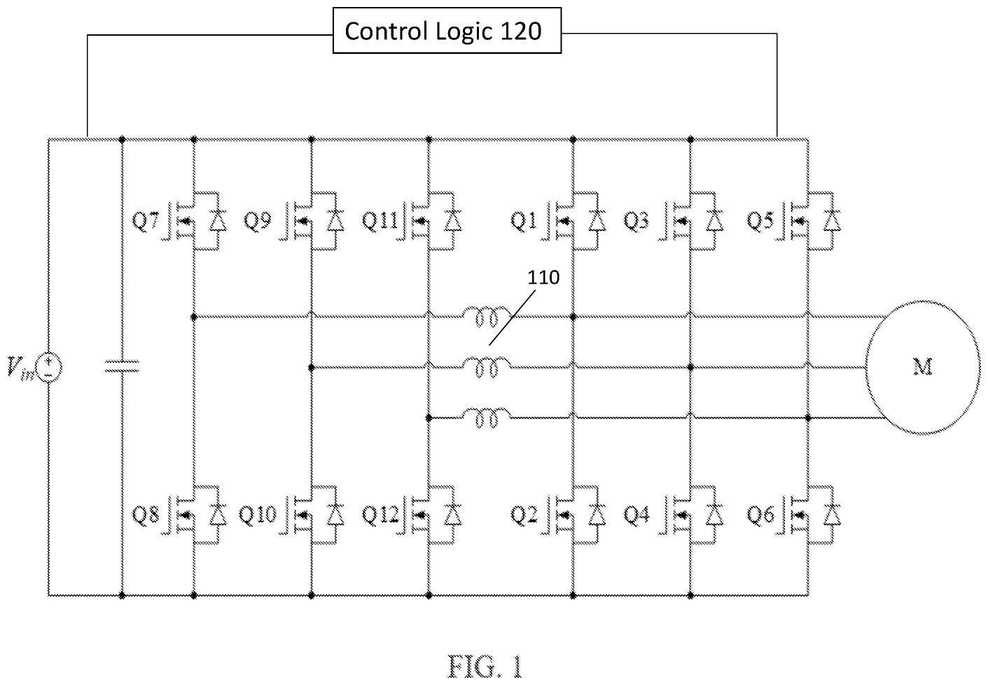

In one aspect, FIG. 1 is the system level circuit structure of a three-phase DC to AC converter, which is constructed on a circuit bearing structure, such as print circuit board (PCB).

In one embodiment, the power converter may include a control logic 110 and a plurality of inductor banks 120, and each inductor bank may include at least one inductor. Also, each inductor bank has first and second nodes. In some embodiments, an inductor in an inductor bank may be the parasitic inductance of a circuit bearing structure. The circuit also includes a plurality of switches Q1, Q2, Q3, Q4, Q5, Q6, Q7, Q8, Q9, Q10, Q11 and Q12, and each switch has respective first and second power nodes and a control node. The input of control signal maintains the switch in either ON state in which the circuit path between the first node and the second node are established, or OFF state in which the circuit path between the first node and the second node are eliminated. As shown in FIG. 1, in one embodiment, N-channel SiC MOSFETs are used. However, any other types of SiC material based switches can be also used.

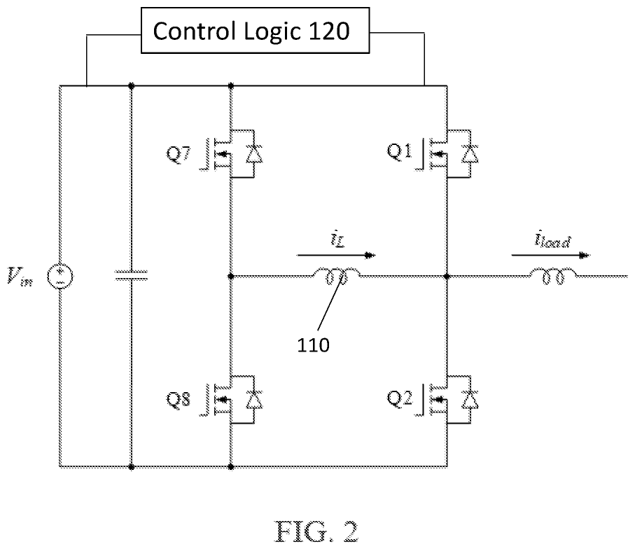

FIG. 2 is the circuit diagram of the one phase circuit of the three-phase circuit shown in FIG. 1. In the one phase circuit, there are two main power switches, two auxiliary switches and one inductor bank. By controlling the two auxiliary switches, the two main power switches can switch at zero voltage condition.

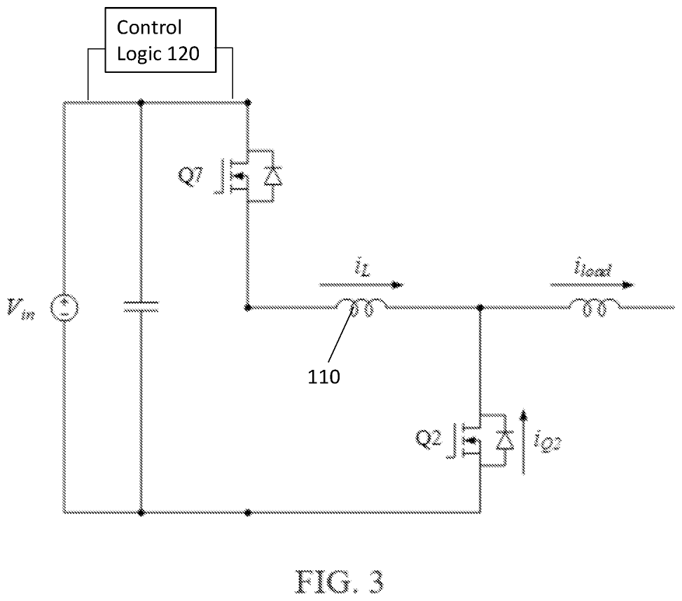

FIG. 3 is the circuit diagram of the first sub-circuit of the one phase circuit shown in FIG. 2. When switches Q2 and Q7 are in “on” state, the current flowing through the inductor bank is increasing linearly, energy will be stored in the inductor bank with this specific sub-circuit.

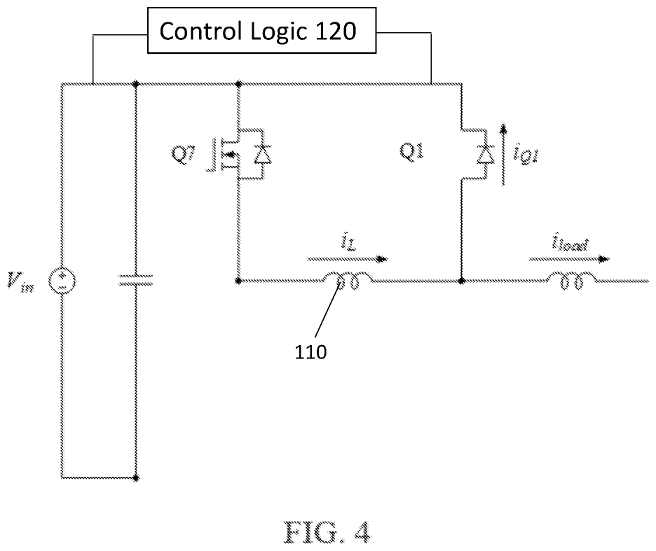

FIG. 4 is the circuit diagram of the second sub-circuit of the one phase circuit shown in FIG. 2. When the inductor current is high enough, the main power switch Q2 turns OFF, the inductor bank starts to make the voltage across the first and second power nodes of the main power switch to decrease.

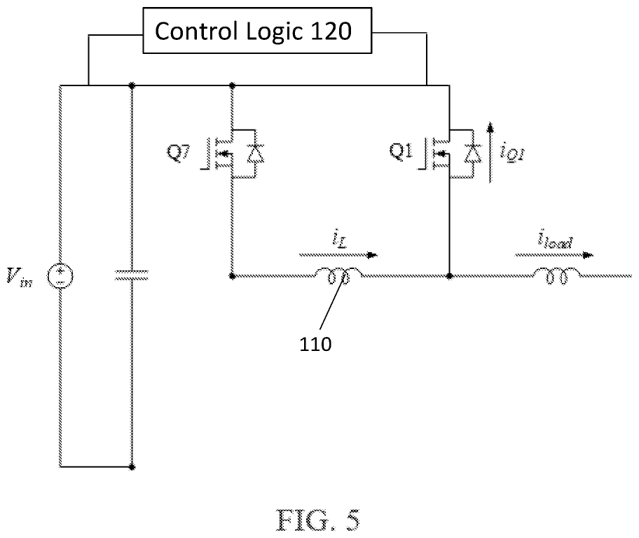

FIG. 5 is the circuit diagram of the third sub-circuit of the one phase circuit shown in FIG. 2. When the voltage across the first and second power nodes of the main power switch decreases to zero, the Q2's complimentary main power Q1 changes from OFF state to ON state, zero-voltage switching is implemented.

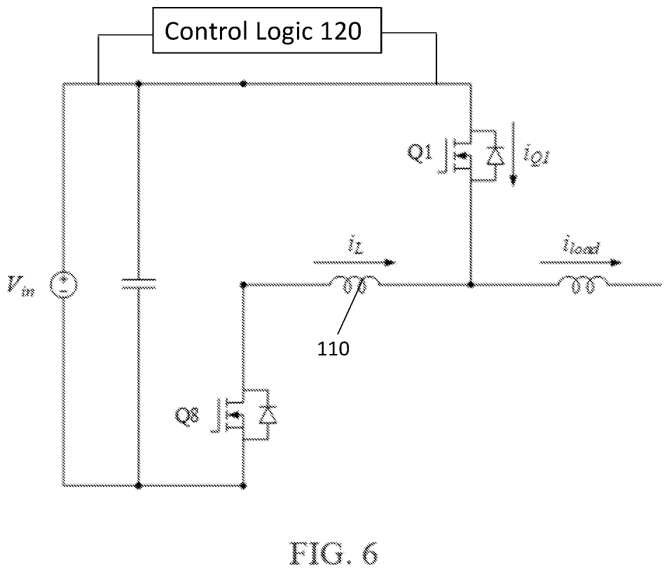

FIG. 6 is the circuit diagram of the fourth sub-circuit of the one phase circuit shown in FIG. 2. After the implementation of zero-voltage switching, auxiliary switch Q8 change from OFF state to ON state, Q7 change from ON state to OFF state, to reset the current flowing through the inductor bank back to zero.

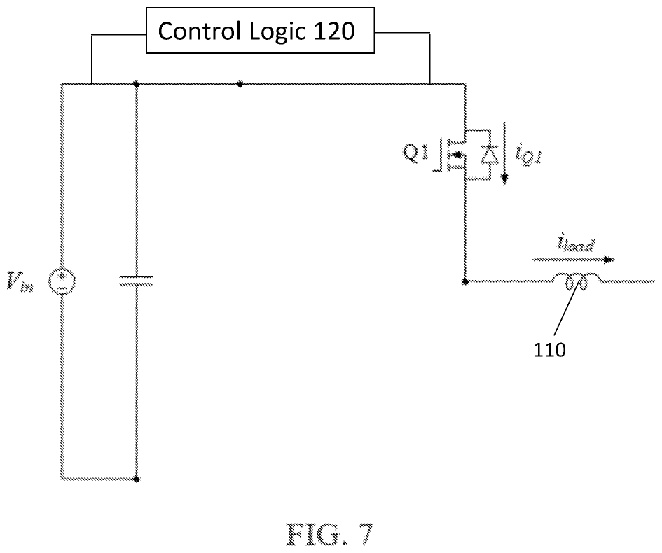

FIG. 7 is the circuit diagram of the fifth sub-circuit of the one phase circuit shown in FIG. 2. When the energy stored in the inductor bank is fully discharged, this specific circuit can maintain the inductor bank current at zero level.

In some implementations, the control logic 110 controls the second stage switches to turn-on and turn-off at zero current, therefore the zero current switching can be achieved. This control mechanism gives the lossless switching feature to the part of the circuit.

In summary, the present invention relates to a three-phase full SiC inverter with zero-voltage switching capability. The inverter system may include a plurality of switches that are connected to the circuit nodes; a plurality of inductor banks that are connected to the non-ground circuit nodes. The switches are controlled by the control logic that generates different control signals which are applied to the control nodes of the switches. In addition, the control logic generates signals that allows auxiliary circuits to ensure the main power switches in the circuit to turn on and off at zero voltage.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A power converter comprising:
a plurality of inductor banks;
a plurality of switches, each switch has a first power node and a second power node, and one control node that receives a control signal that maintains the switch in either ON state in which the circuit path between the first node and the second node are established, or OFF state in which the circuit path between the first node and the second node are eliminated; and
a control logic that generates multiple signals that are applied to the control nodes of the switches to control some switches to turn-on and turn-off at zero current to achieve zero current switching.

2. The power converter of claim 1, wherein each first power node and each second power node of each switch is connected to a respective circuit node in the circuit, and each inductor bank includes at least one inductor that have two nodes that are connected to respective circuit nodes in a circuit.

3. The power converter of claim 1, wherein the control logic generates control signals to cause zero voltage switching on each main power switch.

4. The power converter of claim 1, wherein each inductor in the inductor bank is a parasitic inductance of a circuit bearing structure.

5. The power converter of claim 1, wherein at least one sub-circuit loop includes one auxiliary switch, one inductor bank and one main power switch.

6. The power converter of claim 1, wherein the switches are MOSFETs; the first power nodes are drains and the second power nodes are sources, and the control nodes are gates.

7. The power converter of claim 1, wherein the inductor bank that have two nodes connected to respective circuit nodes in a circuit.

8. The power converter of claim 1, wherein at least one circuit node connects with input voltage and at least one circuit node connects with output voltage.
